(19) United States
(12) Patent Application Publication
(10) Pub. No.: US 2024/0355666 A1
(43) Pub. Date: Oct. 24, 2024

(54) SUBSTRATE TRANSFERRING APPARATUS

(71) Applicant: Samsung Electronics Co., Ltd., Suwon-si (KR)

(72) Inventors: Sung-Il Choi, Suwon-si (KR); Seong-Eun Kang, Suwon-si (KR); Kyung Beom Kim, Suwon-si (KR); Sung Yoon Ryu, Suwon-si (KR); Mi Ra Park, Suwon-si (KR); Yong Kyu Lee, Suwon-si (KR); Jeung Hee Lee, Suwon-si (KR); Ju Hyun Lee, Suwon-si (KR); Nam Young Cho, Suwon-si (KR)

(21) Appl. No.: 18/636,612

(22) Filed: Apr. 16, 2024

(30) Foreign Application Priority Data
Apr. 19, 2023 (KR) 10-2023-0051376
Jun. 5, 2023 (KR) 10-2023-0072303

(51) Int. Cl. H01L 21/683; H01L 21/687

(52) U.S. Cl. CPC H01L 21/6838; H01L 21/68707

(57) ABSTRACT

A substrate transferring apparatus includes a support plate including an upper surface on which a substrate is configured to be seated, and a vacuum pad detachably coupled to the support plate and configured to vacuum suction the substrate to fix the substrate on the upper surface of the support plate, wherein the vacuum pad includes a suction area and a support protrusion surrounding the suction area, an upper surface of the support protrusion is at a higher vertical level than an upper surface of the suction area to support the substrate, and the upper surface of the support protrusion is inclined relative to horizontal.

### CROSS-REFERENCE TO RELATED APPLICATION

This application claims priority under 35 U.S.C. 119 from Korean Patent Application No. 10-2023-0051376 filed on Apr. 19, 2023 and No. 10-2023-0072303 filed on Jun. 5, 2023 in the Korean Intellectual Property Office, the contents of which in their entirety are herein incorporated by reference.

### BACKGROUND

The present disclosure relates to a substrate transferring apparatus.

Wafer transfer robots are used to transfer wafers in semiconductor manufacturing facilities. The wafer transfer robot may have an arm blade that acts like a robot hand to support the wafers. Each arm blade may include a chucking member for preventing the wafer from being separated from the corresponding robot during the transfer process. An example of such a chucking member involves a vacuum method for fixing the wafer to the arm blade using vacuum pressure, and a vacuum pad for vacuum sucking the wafer using vacuum pressure may be installed on the arm blade.

When the wafer is fixed to the arm blade by the vacuum method, the wafer continuously rubs against the vacuum pad, which may cause abrasion on a surface of the vacuum pad. As a result, an accident in which the wafer is not stably fixed on the arm blade and slips may occur. On the other hand, as high integration of the semiconductor process is achieved, a phenomenon in which high-temperature heat is applied to the wafer or the wafer is warped frequently occurs. In response to such a change in the state of the wafer, research on a method for stably transferring the wafer is in progress.

### SUMMARY

Aspects of the present disclosure provide a substrate transferring apparatus including a vacuum pad with improved reliability so as to stably transfer a substrate during semiconductor manufacturing.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a substrate transferring apparatus includes a support plate including an upper surface on which a substrate is configured to be seated, and a vacuum pad detachably coupled to the support plate and configured to vacuum suction the substrate to fix the substrate on the upper surface of the support plate, wherein the vacuum pad includes a suction area and a support protrusion surrounding the suction area, an upper surface of the support protrusion is at a higher vertical level than an upper surface of the suction area to support the substrate, and the upper surface of the support protrusion is inclined relative to horizontal.

According to an aspect of the present disclosure, a substrate transferring apparatus includes a support plate including an upper surface on which a substrate is configured to be seated, a coupling groove extending downward from the upper surface, a first bolt insertion hole defined in a central part of the coupling groove, and a bolt fastener in the first bolt insertion hole, a vacuum pad including a suction area, a support protrusion surrounding the suction area, and a second bolt insertion hole formed in a central part of the suction area, and a bolt simultaneously penetrating through the first bolt insertion hole and the second bolt insertion hole and fastened to the bolt fastener, wherein the bolt includes a vacuum hole penetrating therethrough, and the vacuum hole is connected to a vacuum passage defined inside the support plate.

According to an aspect of the present disclosure, a substrate transferring apparatus includes a first supporting arm extending in a first direction and including an upper surface on which a substrate is configured to be seated, a second supporting arm spaced apart from the first supporting arm in a second direction intersecting the first direction, extending in the first direction, and having an upper surface on which the substrate is configured to be seated, a connecting arm connecting the first supporting arm and the second supporting arm and extending in the second direction; and a vacuum pad on the upper surface of at least one of the first supporting arm and the second supporting arm and configured to vacuum suction the substrate to fix the substrate on the upper surface of at least one of the first supporting arm and the second supporting arm, wherein the vacuum pad includes a base and a support protrusion surrounding the base, and is detachably coupled to at least one of the first and second supporting arms by a bolt, the bolt is coupled to a central part of the vacuum pad, an upper surface of the support protrusion is at a higher vertical level than an upper surface of the base to support the substrate, the upper surface of the support protrusion is inclined relative to horizontal, a protrusion wall is on the upper surface of the support protrusion, the protrusion wall includes a first protrusion having a first height and a second protrusion having a second height, and the first height is higher than the second height.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example view for describing a substrate transferring apparatus according to some example embodiments.

FIG. 2 is a partial plan view illustrating the support plate illustrated in FIG. 1.

FIG. 3 is a cross-sectional view taken along line I-I of FIG. 2.

FIG. 4 is an enlarged view of region II of FIG. 2.

FIG. 5 is a view illustrating the vacuum pad and the bolt in FIG. 4 separated from each other.

FIG. 6 is an example view illustrating the vacuum pad of FIG. 4.

FIG. 7 is a cross-sectional view taken along line III-III of FIG. 6.

FIG. 8 is an enlarged view of region IV of FIG. 7.

FIG. 9 is a cross-sectional view taken along line V-V of FIG. 8.

FIGS. 10 and 11 are views for describing the protruding wall illustrated in FIG. 9.

FIG. 12 is an example view for describing a vacuum pad included in the substrate transferring apparatus according to some other example embodiments.

FIG. 13 is a cross-sectional view taken along line VI-VI of FIG. 12.

FIG. 14 is a cross-sectional view taken along line VII-VII of FIG. 13.

FIG. 15 is an example view for describing a substrate vacuum adsorbed by the vacuum pad illustrated in FIG. 12.

FIGS. 16 and 17 are example views for describing protruding walls formed on upper surfaces of support protrusions of the vacuum pad illustrated in FIG. 12.

FIG. 18 is an example view for describing a vacuum pad included in the substrate transferring apparatus according to some still other example embodiments.

FIG. 19 is a cross-sectional view taken along line VIII-VIII of FIG. 18.

FIG. 20 is a cross-sectional view taken along line IX-IX of FIG. 19.

FIG. 21 is an example view for describing a substrate vacuum adsorbed by the vacuum pad illustrated in FIG. 18.

FIGS. 22 and 23 are example views for describing protruding walls formed on upper surfaces of support protrusions of the vacuum pad illustrated in FIG. 18.

FIG. 24 is an example view for describing a vacuum pad included in the substrate transferring apparatus according to some still other example embodiments.

FIG. 25 is an enlarged view of region X of FIG. 24.

### DETAILED DESCRIPTION

Hereinafter, a substrate transferring apparatus according to some example embodiments will be described with reference to the accompanying drawings.

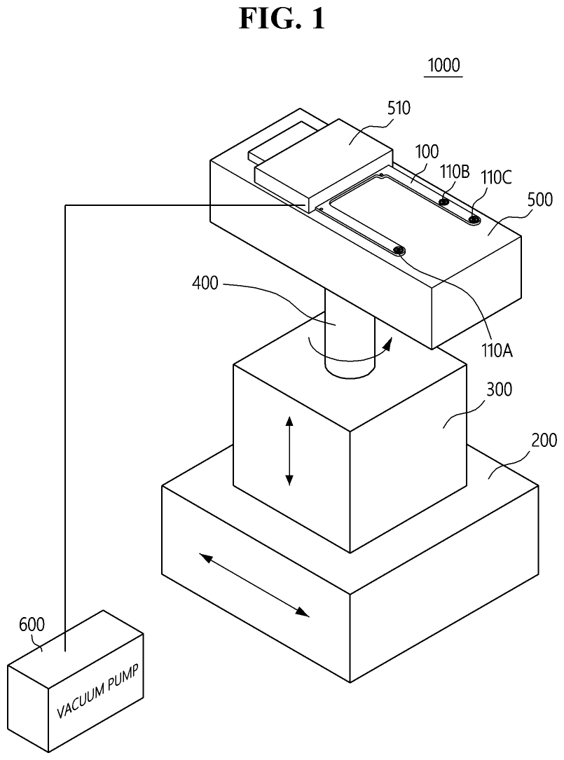

FIG. 1 is an example view for describing a substrate transferring apparatus according to some example embodiments.

Referring to FIG. 1, a substrate transferring apparatus or substrate transfer apparatus 1000 may include a horizontal moving portion 200, a vertical moving portion 300, a rotating portion 400, an arm support portion 500, a support plate 100, and vacuum pads 110A, 110B, and 110C. The substrate transferring apparatus 1000 may transfer a wafer (or a substrate) to a desired position while moving within a substrate processing system. For example, the wafer transferred by the substrate transferring apparatus 1000 may be a wafer provided for producing memory chips such as dynamic random access memory (DRAM) or NAND flash, but is not limited thereto. The wafer transferred by the substrate transferring apparatus 1000 may be a wafer in a state in which a process of processing a substrate, such as depositing a material film on a substrate, is performed to produce a semiconductor device, or may be a wafer in a state in which various processes of processing a substrate are being performed.

Here, the substrate may refer to a substrate itself or a laminated structure including a predetermined layer or film formed on a surface of the substrate. In addition, the substrate may be a wafer or may include a wafer and at least one material film on the wafer. The material film may be an insulating film and/or a conductive film formed on a wafer through various methods such as deposition, coating, and plating. For example, the insulating film may include an oxide film, a nitride film, or an oxynitride film, and the conductive film may include a metal film or a polysilicon film. Meanwhile, the material film may also be formed on the wafer in a predetermined pattern.

In some example embodiments, the substrate transferring apparatus 1000 may be a transfer robot that transfers a wafer in a state in which a substrate processing process is performed in a substrate processing system from a chamber in which the process is performed to a measurement device or a test device.

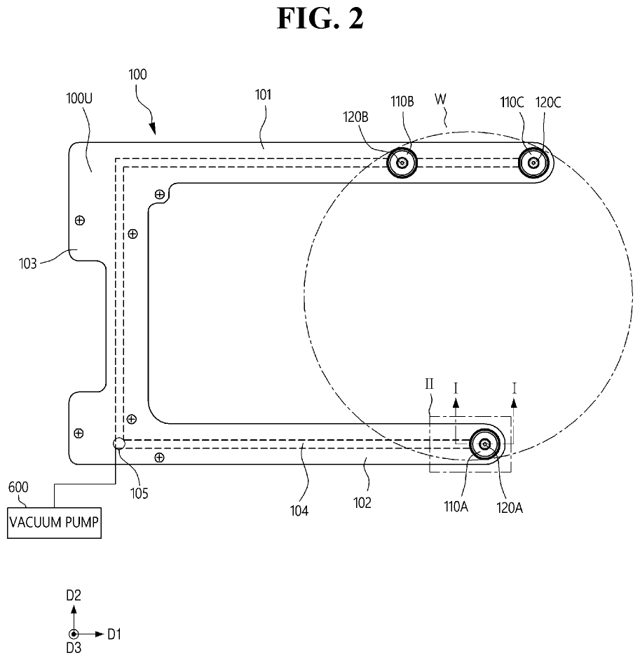

The substrate may be seated on an upper surface of the support plate 100. The substrate transferring apparatus 1000 may move in a state in which the substrate is seated on the support plate 100 and transfer the substrate to a desired position. Detachable vacuum pads 110A, 110B, and 110C may be coupled to the support plate 100. The vacuum pads 110A, 110B, and 110C may vacuum suction the substrate to stably fix the substrate on the upper surface of the support plate 100. To this end, a vacuum pump 600 may be connected to the support plate 100 to provide vacuum pressure for vacuum suction of the vacuum pads 110A, 110B, and 110C. The support plate 100 and the vacuum pads 110A, 110B, and 110C will be described below with reference to FIG. 2 and the like.

The support plate 100 may be fixed on the arm support portion 500 by a fixing member 510. The rotating portion 400 may be installed on a lower side of the arm support portion 500. The rotating portion 400 may be coupled to the arm support portion 500 and rotated to rotate the arm support portion 500. Accordingly, the arm support portion 500 and the support plate 100 may be rotated together. The vertical moving portion 300 may be installed on a lower side of the rotating portion 400, and the horizontal moving portion 200 may be installed on a lower side of the vertical moving portion 300. The vertical moving portion 300 may be coupled to the rotating portion 400 to raise or lower the rotating portion 400, and accordingly, a vertical position of the support plate 100 may be adjusted. The horizontal moving portion 200 may horizontally move along a predetermined path (e.g., along a transfer rail) within a substrate processing system of a semiconductor manufacturing facility to transfer a wafer to a desired position.

FIG. 2 is a partial plan view illustrating the support plate illustrated in FIG. 1.

Referring to FIG. 2, the support plate 100 may include a first supporting arm or first support arm 101, a second supporting arm or second support arm 102, and a connecting arm or connection arm 103. The supporting arm 101 and the supporting arm 102 may extend in a first direction D1, and may be spaced apart from each other in a second direction D2 intersecting or perpendicular to the first direction D1. The connecting arm 103 may extend in the second direction D2 to connect one end of the supporting arm 101 and one end of the supporting arm 102. As such, the support plate 100 may have a ‘U’ shape including the supporting arms 101 and 102 and the connecting arm 103, but the shape of the support plate 100 is not limited thereto.

The vacuum pads 110A, 110B, and 110C may be detachably coupled to an upper surface 100U of the support plate 100. For example, the vacuum pads 110A, 110B, and 110C may be detachably coupled to the support plate 100 by fasteners such as bolts 120A, 120B, and 120C, respectively. Therefore, when any one of the vacuum pads 110A, 110B, and 110C is worn or damaged and needs to be replaced, only the vacuum pads that need to be replaced among the vacuum pads 110A, 110B, and 110C may be replaced without replacing the entire support plate 100 in the substrate transferring apparatus 1000 (illustrated in FIG. 1). As a result, it is possible to reduce replacement costs and reduce backup time. It is illustrated in FIG. 2 that two vacuum pads 110B and 110C are coupled to the supporting arm 101 and one vacuum pad 110A is coupled to the supporting arm 102, but the example embodiment is not limited thereto. For example, the number and/or arrangement of vacuum pads coupled to the support plate 100 of the substrate transferring apparatus 1000 may vary depending on the example embodiment. The vacuum pads 110A, 110B, and 110C may have a circular shape as illustrated in FIG. 2, but the shape of the vacuum pads 110A, 110B, and 110C is not limited thereto. For example, in some example embodiments, the vacuum pad may have a quadrangular shape.

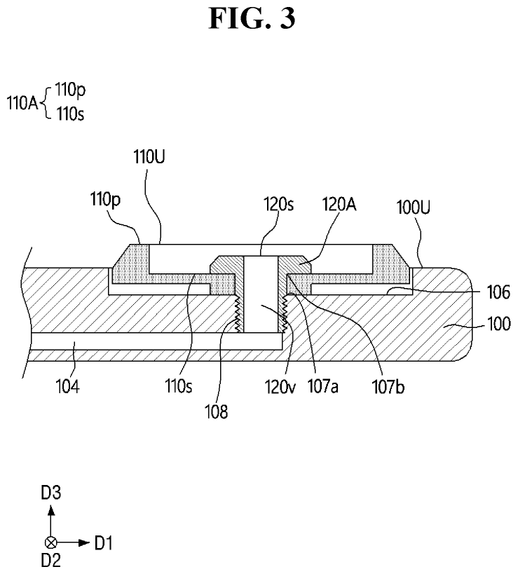

A substrate W may be seated on the upper surface 100U of the support plate 100. In this case, the vacuum pads 110A, 110B, and 110C may fix the substrate W on the upper surface 100U of the support plate 100 by vacuum sucking a lower surface of the substrate W. A vacuum passage 104 may be formed inside the support plate 100. In addition, a hole 105 connected to the vacuum pump 600 outside the support plate 100 may be formed in the upper surface 100U of the support plate 100. The hole 105 may be connected to the vacuum passage 104 inside the support plate 100, and the vacuum passage 104 may connect or extend between the hole 105 and the vacuum pad 110A, between the hole 105 and the vacuum pad 110B, and between the vacuum pad 110B and the vacuum pad 110C. Accordingly, when the vacuum pump 600 performs a vacuum pumping operation, vacuum pressure is provided to the substrate W seated on the vacuum pads 110A, 110B, and 110C along the vacuum passage 104 so that the substrate W may be vacuum sucked on the vacuum pads 110A, 110B, and 110C. The vacuum suction of the substrate W by the vacuum pads 110A, 110B, and 110C will be described below in detail with reference to FIG. 3.

Since the vacuum pads 110A, 110B, and 110C have the same configuration as each other, a configuration of each of the vacuum pads 110A, 110B, and 110C will be specifically described below using the vacuum pad 110A as an example, and the description of the configuration of the vacuum pads 110B and 110C will be omitted in the interest of brevity. FIG. 3 is a cross-sectional view taken along line I-I of FIG. 2.

Referring to FIG. 3, the support plate 100 may include a coupling groove 106 drawn or extending from the upper surface 100U thereof, a bolt insertion hole 107a formed in a center or a central part of the coupling groove 106, and a bolt fastener 108 (e.g., threads) to which a bolt 120A is fastened (e.g., threaded). The bolt insertion hole 107a may be formed to penetrate through a portion of the support plate 100 from the center or the central part of the coupling groove 106 in a third direction D3. The bolt fastener 108 may be installed in the bolt insertion hole 107a.

The vacuum pad 110A may be inserted into the coupling groove 106 of the support plate 100. The vacuum pad 110A may include a suction area 110s (also referred to herein as a base 110s) and a support protrusion 110p. The suction area 110s of the vacuum pad 110A is or includes an area adjacent to the center or the central part of the vacuum pad 110A, and may be formed by being drawn or extended inward from the upper surface 110U of the vacuum pad 110A. As such, as the suction area 110s has a shape drawn from the upper surface 110U of the vacuum pad 110A, an empty space for vacuum suction may be provided when the substrate W is disposed on the vacuum pad 110A and vacuum sucked.

The support protrusion 110p may have a shape surrounding the suction area 110s and may have a shape protruding more than the suction area 110s. In other words, the suction area or base 110s may include an upper surface, and the support protrusion 110p may extend upwardly away from the upper surface. For example, an upper surface of the support protrusion 110p may be defined as the upper surface 110U of the vacuum pad 110A. A bolt insertion hole 107b may be formed in a center or a central part of the suction area 110s. The bolt insertion hole 107b may be formed to penetrate through the vacuum pad 110A in the third direction D3 from the center or the central part of the suction area 110s.

In a state in which the vacuum pad 110A is inserted into the coupling groove 106, the bolt 120A may be fastened to the bolt fastener 108 by simultaneously penetrating through the bolt insertion hole 107b of the vacuum pad 110A and the bolt insertion hole 107a of the support plate 100. The bolt 120A may include a vacuum hole or vacuum channel 120v penetrating through the inside thereof in the third direction D3. The vacuum hole 120v of the bolt 120A may be connected to the vacuum passage 104 formed inside the support plate 100. In addition, a suction hole 120s connected to the vacuum hole 120v may be formed on an upper surface of the bolt 120A. Accordingly, when the vacuum pump 600 (illustrated in FIG. 2) is driven, the substrate W seated on the vacuum pad 110A is sucked to the vacuum pad 110A by vacuum pressure, and thus the substrate W may be fixed to the support plate 100.

When the substrate W is vacuum sucked on the vacuum pad 110A, the substrate W may come into contact with the support protrusion 110p and be supported by the support protrusion 110p. In this case, the substrate W may be only in contact with an upper surface of the support protrusion 110p and may not be in contact with an upper surface of the suction area 110s (e.g., the substrate W may be spaced apart from the suction area or base 110s). That is, since the upper surface of the support protrusion 110p protrudes more or is at a higher vertical level than the upper surface of the suction area 110s, a portion actually in contact with the substrate W during vacuum suction may be the upper surface of the support protrusion 110p, and the upper surface of the suction area 110s may not be worn or may be less worn than the upper surface of the support protrusion 110p. In addition, when the high-temperature substrate W is seated on the support plate 100, a portion that is greatly affected by high temperature among the components of the vacuum pad 110A may be the support protrusion 110p, and the suction area 110s may be relatively less affected by high temperatures.

Accordingly, in some example embodiments, when the substrate W seated on the support plate 100 is in a high temperature state, the vacuum pad 110A may be made of two different materials. For example, the support protrusion 110p in contact with the high-temperature substrate W may include a ceramic material, and the suction area 110s not in contact with the substrate W may include a plastic material. For example, the support protrusion 110p may include a ceramic material such as aluminum oxide (Al₂O₃) or sintered silicon carbide (SSiC), and the suction area 110s may include a plastic material such as Ertalyte. In this way, by implementing the support protrusion 110p in direct contact with the high-temperature substrate W among the components of the vacuum pad 110A with a ceramic material with strong heat resistance, and implementing the suction area 110s, which is not in direct contact with the high-temperature substrate W, with a cheaper material than the support protrusion 110p, the maintenance cost of the vacuum pad 110A may be reduced.

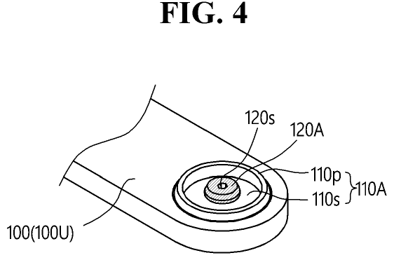

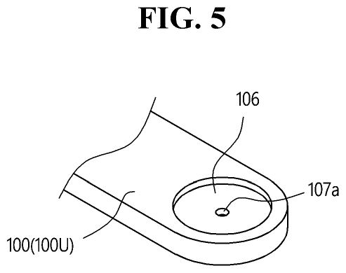

FIG. 4 is an enlarged view of region II of FIG. 2. FIG. 5 is a view illustrating the vacuum pad and the bolt in FIG. 4 separated from each other.

Referring to FIGS. 4 and 5, the bolt insertion hole 107a of the support plate 100 may be formed in the center or the central part of the coupling groove 106. In addition, the bolt insertion hole 107b (illustrated in FIG. 3) of the vacuum pad 110A may be formed in the center or the central part of the suction area 110s. Accordingly, when the bolt 120A fastens the vacuum pad 110A to the support plate 100, the center or the central part of the vacuum pad 110A is fixed to the support plate 100 by the bolt, but an edge portion of the vacuum pad 110A may not be completely fixed to the support plate 100. Accordingly, when the vacuum pad 110A vacuum-sucks the substrate W, the edge portion of the vacuum pad 110A may move up and down by a predetermined interval while having fluidity. Accordingly, when the substrate W seated on the upper surface 100U of the support plate 100 is not horizontal to a plane on which the support plate 100 is disposed and has a warped shape, and the vacuum pad 110A sucks the warped substrate W, the edge portion of the vacuum pad 110A may move up and down by a predetermined interval while having fluidity depending on a direction in which the substrate W is curved, and thus the warped substrate W may be stably sucked and fixed.

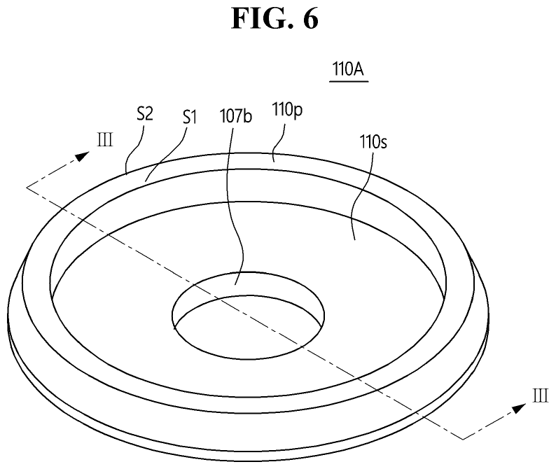

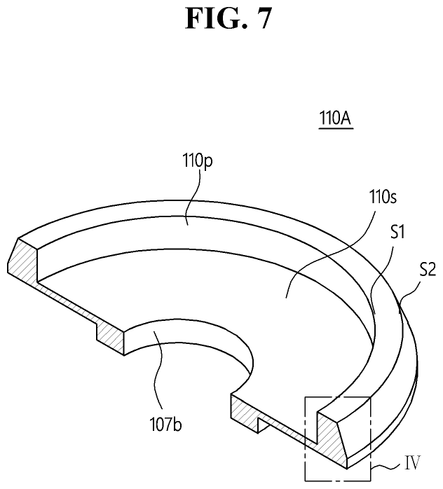

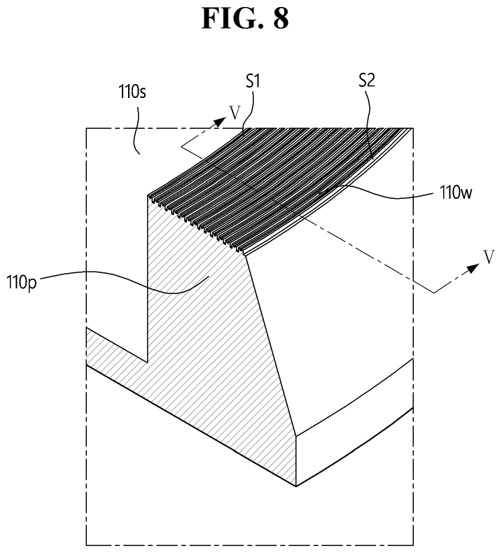

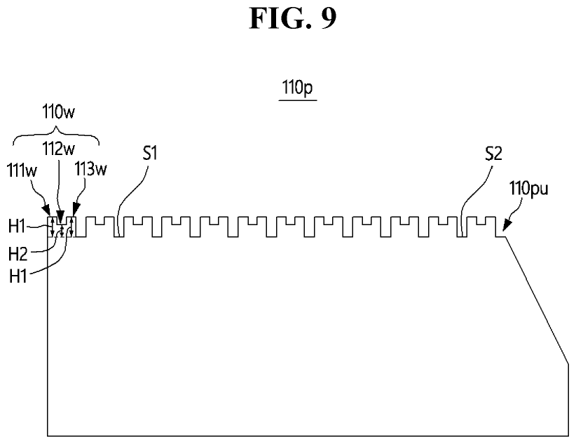

FIG. 6 is an example view illustrating the vacuum pad of FIG. 4. FIG. 7 is a cross-sectional view taken along line III-III of FIG. 6. FIG. 8 is an enlarged view of region IV of FIG. 7. FIG. 9 is a cross-sectional view taken along line V-V of FIG. 8. A vacuum pad included in the substrate transferring apparatus according to some example embodiments will be described with reference to FIGS. 6 to 9.

As described above, the vacuum pad 110A may include the suction area 110s, the support protrusion 110p, and the bolt insertion hole 107b. An upper surface of the support protrusion 110p may include a first area or first circumference or inner circumference S1 and a second area or second circumference or outer circumference S2. The first area SI may be closer to the center or the central part of the vacuum pad 110A than the second area S2. That is, a distance from the first area S1 of the support protrusion 110p to the center or the central part of the vacuum pad 110A may be shorter than a distance from the second area S2 of the support protrusion 110p to the center or the central part of the vacuum pad 110A. In this case, a vertical height from the lower surface of the vacuum pad 110A to the first area S1 may be the same as a vertical height from the lower surface of the vacuum pad 110A to the second area S2. Accordingly, the support protrusion 110p of the vacuum pad 110A may have a flat upper surface without an inclination.

Referring to FIGS. 8 and 9 together, a protrusion wall or protruding wall 110w may be disposed on the upper surface of the support protrusion 110p. The protrusion wall 110w may include protrusions or ridges 111w and 113w having a height H1 and a protrusion or ridge 112w disposed between the protrusions 111w and 113w and having a height H2. The heights H1 and H2 may be vertical heights at which the protrusions 111w, 112w, and 113w protrude from an upper surface 110pu of the support protrusion 110p. The protrusions 111w, 112w, and 113w may extend and be disposed on the upper surface 110pu of the support protrusion 110p in a concentric circle shape surrounding the suction area 110s. In addition, the number of protrusion walls 110w including the protrusions 111w, 112w, and 113w is plural, and the plurality of protrusion walls 110w may extend and be disposed on the upper surface 110pu of the support protrusion 110p in a concentric circle shape surrounding the suction area 110s. The plurality of protrusion walls 110w may be spaced apart from one another. The height H1 of the protrusions 111w and 113w may be higher than the height H2 of the protrusion 112w disposed therebetween. In some example embodiments, a ratio of the height H2 to the height H1 may be ⅖ or more and ⅘ or less. For example, when the height H1 of the protrusion 111w is about 5 mm, the height H2 of the protrusion 112w may be about 3 mm.

When the substrate W is seated on the support plate 100 (illustrated in FIG. 2) and the vacuum pad 110A vacuum sucks the substrate W, the protruding wall 110w may be an indicator for visually checking the degree of wear of the vacuum pad 110A and the corresponding replacement cycle of the vacuum pad 110A. For example, a user of the substrate transferring apparatus 1000 (illustrated in FIG. 1) may check the degree of wear of the protrusion wall 110w installed on the upper surface 110pu of the support protrusion 110p and may replace the vacuum pad 110A at an appropriate time according to the check result.

Specifically, when the protrusions 111w and 113w, which protrude more than the protrusion 112w, are worn due to friction with the substrate W and thus the height H1 of the protrusions 111w and 113w becomes equal to the height H2 of the protrusion 112w, or the protrusion 112w is also worn along with the protrusions 111w and 113w as wear due to friction with the substrate W continues and thus the height of the worn protrusions 111w, 112w, and 113w is lower than the original height H2 of the protrusion 112w, the user of the substrate transferring apparatus 1000 may recognize that the vacuum pad 110A needs to be replaced soon.

Thereafter, when the protrusions 111w, 112w, and 113w are completely worn and thus the upper surface 110pu of the support protrusion 110p is smooth without the protrusion wall 110w, or the protrusions 111w, 112w, and 113w are almost worn and thus the upper surfaces of the protrusions 111w, 112w, and 113w are almost even level with the upper surface 110pu of the support protrusion 110p, the user of the substrate transferring apparatus 1000 may replace the vacuum pad 110A with a new one.

In this way, by disposing the protruding wall 110w on the upper surface 110pu of the support protrusion 110p and visually checking the degree of wear of the protruding wall 110w by the user of the substrate transferring apparatus 1000, a phenomenon in which the substrate W is not stably sucked on the vacuum pad 110A and slipped due to excessive wear of the vacuum pad 110A may be prevented.

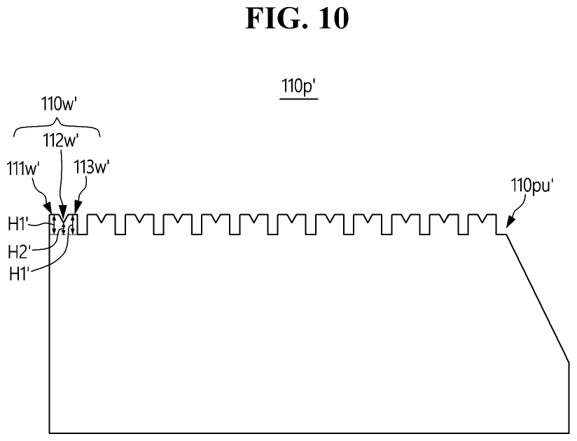

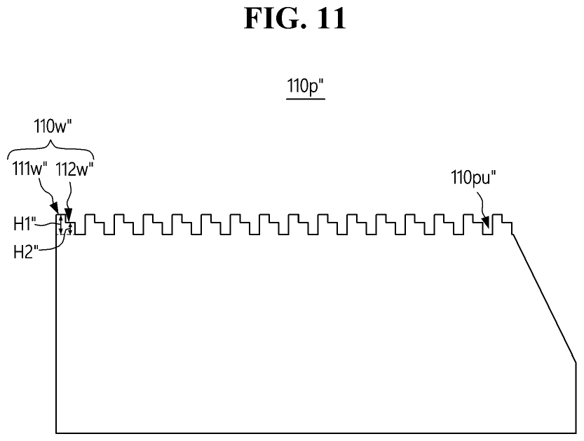

FIGS. 10 and 11 are views for describing the protruding wall illustrated in FIG. 9.

FIGS. 10 and 11 are example views for describing various shapes of the protruding wall 110w illustrated in FIG. 9. Hereinafter, overlapping descriptions with the previous example embodiments may be omitted, and differences will be mainly described, in the interest of brevity. Referring to FIG. 10, a protrusion wall 110w′ disposed on an upper surface 110pu′ of a support protrusion 110p′ may include the protrusions 111w′ and 113w′ having a height H1′ and a protrusion 112w′ disposed between the protrusions 111w′ and 113w′ and having a height H2′. Unlike the protrusion 112w illustrated in FIG. 9, the protrusion 112w′ may have a ‘V’ shape. Stated differently, a space between the protrusions 111w′ and 113w′ may have a ‘V’ shape.

Next, referring to FIG. 11, a protruding wall 110w″ disposed on an upper surface of a support protrusion 110p″ may include a protrusion 111w″ having a height H1″ and a protrusion 112w″ having a height H2″. The height H1″ may be higher than the height H2″, and a ratio of the height H2″ of the protrusion 112w″ to the height H1″ of the protrusion 111w″ may be ⅖ or more and ⅘ or less. For example, when the height H1″ of the protrusion 111w″ is about 5 mm, the height H2″ of the protrusion 112w″ may be about 3 mm.

When the protrusion 111w″ is worn and thus the height H1″ of the protrusion 111w″ becomes equal to the height H2″ of the protrusion 112w″, or the protrusion 112w″ is also worn together and thus the height of the worn protrusions 111w″ and 112w″ is lower than the original height H2″ of the protrusion 112w″, the user of the substrate transferring apparatus 1000 may recognize that the vacuum pad 110A needs to be replaced soon. Thereafter, when the protrusions 111w″ and 112w″ are further worn and thus the upper surfaces of the protrusions 111w″ and 112w″ are almost even level with an upper surface 110pu″ of a support protrusion 110p″, or the protrusions 111w″ and 112w″ are completely worn and thus the upper surface 110pu″ of the support protrusion 110p″ is smooth, the user of the substrate transferring apparatus 1000 may replace the vacuum pad 110A with a new one.

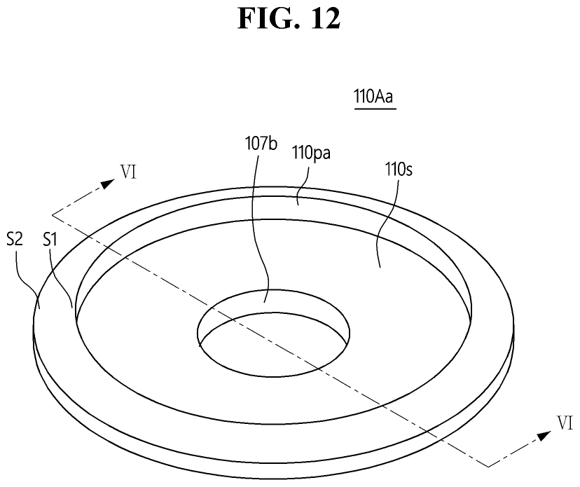

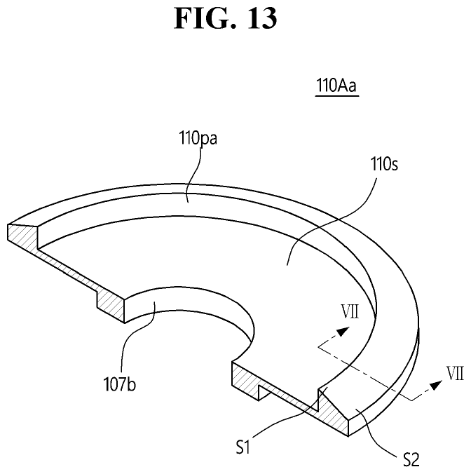

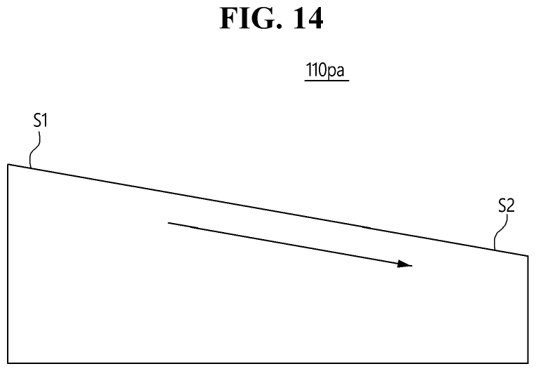

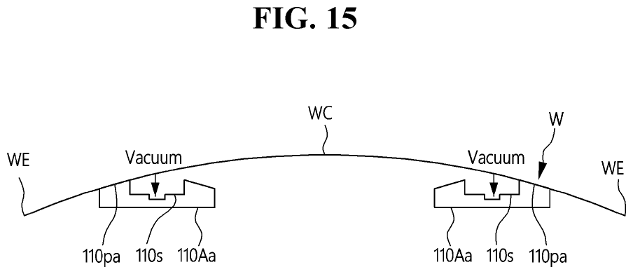

FIG. 12 is an example view for describing a vacuum pad included in the substrate transferring apparatus according to some other example embodiments. FIG. 13 is a cross-sectional view taken along line VI-VI of FIG. 12. FIG. 14 is a cross-sectional view taken along line VII-VII of FIG. 13. FIG. 15 is an example view for describing a substrate vacuum adsorbed by the vacuum pad illustrated in FIG. 12. Hereinafter, a vacuum pad included in the substrate transferring apparatus according to some other example embodiments will be described with reference to FIGS. 12 to 15. In addition, hereinafter, overlapping descriptions with the previous example embodiments may be omitted, and differences will be mainly described, in the interest of brevity.

Referring to FIGS. 12 to 14, unlike illustrated in FIGS. 6 and 7, an upper surface of a support protrusion 110pa of a vacuum pad 110Aa may be inclined (e.g., relative to horizontal). A vertical height from a lower surface of the vacuum pad 110Aa to the first area S1 may be higher than a vertical height from the lower surface of the vacuum pad 110Aa to the second area S2. That is, an inclination in which the vertical height measured from the lower surface of the vacuum pad 110Aa gradually decreases from an area of the upper surface of the support protrusion 110pa closer to a center or a central part of the vacuum pad 110Aa to an area farther from the center or the central part of the vacuum pad 110Aa may be formed. The inclination formed on the upper surface of the support protrusion 110pa as described above may be formed along a direction in which the substrate W is warped, when the substrate W seated on the support plate 100 (illustrated in FIG. 2) and sucked by the vacuum pad 110Aa is warped.

For example, as illustrated in FIG. 15, in the case in which the substrate W is convexly warped and a center (or a central part) WC of the substrate W has a shape that protrudes more than an edge WE of the substrate, when the upper surface of the support protrusion 110p has a flat shape without an inclination as illustrated in FIG. 7, the substrate W may not be stably sucked and fixed on the vacuum pad 110A. However, in the case in which the upper surface of the support protrusion 110pa of the vacuum pad 110Aa in direct contact with the substrate W is formed to have an inclination along the direction in which the substrate W is warped, the substrate W may be stably sucked and fixed on the support plate 100 (illustrated in FIG. 2) and the vacuum pad 110Aa, when the vacuum pad 110Aa vacuum sucks the convexly warped substrate W.

However, the shape of the substrate W vacuum sucked by the vacuum pad 110Aa in which the height of the first area S1 is higher than the height of the second area S2 is not limited to the convex shape in which the center (or the central part) WC of the substrate protrudes more than the edge WE of the substrate. For example, the substrate W vacuum sucked by the vacuum pad 110Aa may have a warped shape corresponding to the inclination formed on the upper surface of the support protrusion 110pa of the vacuum pad 110Aa so as to be stably fixed and sucked by the vacuum pad 110Aa. In addition, although the illustration of the support plate 100 is omitted for convenience of illustration in FIG. 15, the vacuum pad 110Aa may be detachably coupled to the support plate 100 through the bolt 120A (illustrated in FIG. 2).

In addition, as described above, when the vacuum pad 110Aa is coupled to the support plate 100 by the bolt 120A, the center or the central part of the vacuum pad 110Aa is fixed by the bolt 120A, but the edge portion of the vacuum pad 110Aa is not completely fixed to the support plate 100 and may move up and down by a predetermined interval while having fluidity. Accordingly, when the substrate W has the convexly warped shape, the edge portion of the vacuum pad 110Aa moves up and down by a predetermined interval while having fluidity along the direction in which the substrate W is warped, so that the convexly warped substrate W may be stably sucked and fixed.

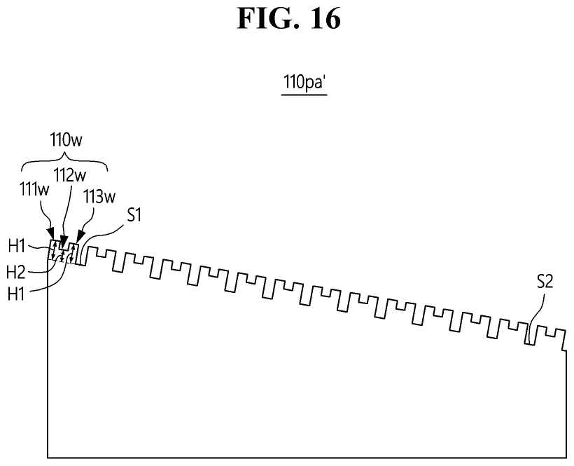

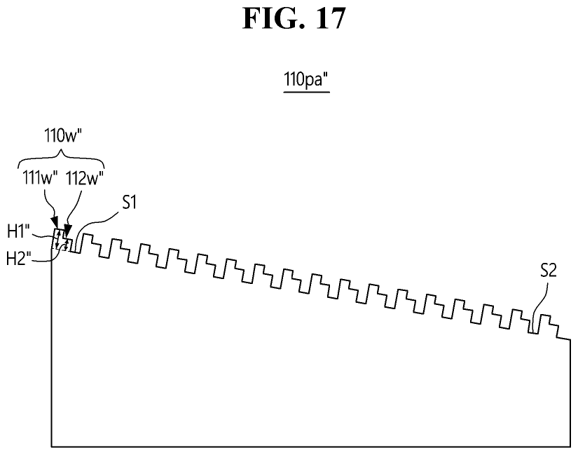

FIGS. 16 and 17 are example views for describing protruding walls formed on upper surfaces of support protrusions of the vacuum pad illustrated in FIG. 12.

Referring to FIGS. 16 and 17, even when an inclination in which the vertical height measured from the lower surface of the vacuum pad 110Aa gradually decreases from an area S1 closer to a center or a central part of the vacuum pad 110Aa to an area S2 farther from the center or the central part of the vacuum pad 110Aa is formed on upper surfaces of support protrusions 110pa′ and 110pa″ of the vacuum pad 110Aa, the protrusion walls 110w and 110w″ as illustrated in FIGS. 9 and 11 may be disposed on the upper surfaces of the support protrusions 110pa′ and 110pa″. Accordingly, the user of the substrate transferring apparatus 1000 (illustrated in FIG. 1) may replace the vacuum pad 110Aa at an appropriate time according to the degree of wear of the protrusion walls 110w and 110w″. Therefore, when the substrate transferring apparatus 1000 transfers the substrate W, it is possible to prevent the substrate W from slipping and being separated from the substrate transferring apparatus 1000 without being stably fixed and sucked on the vacuum pad 110Aa.

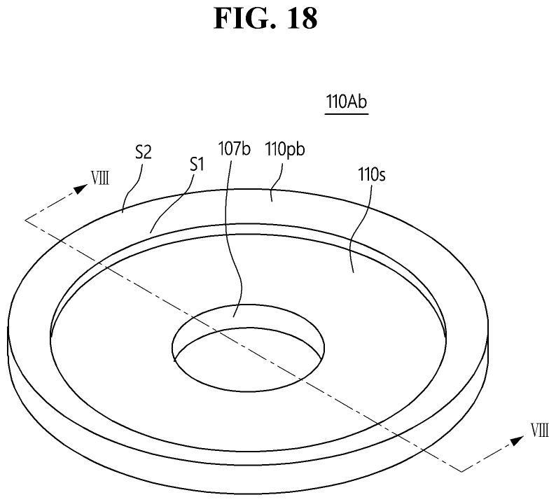

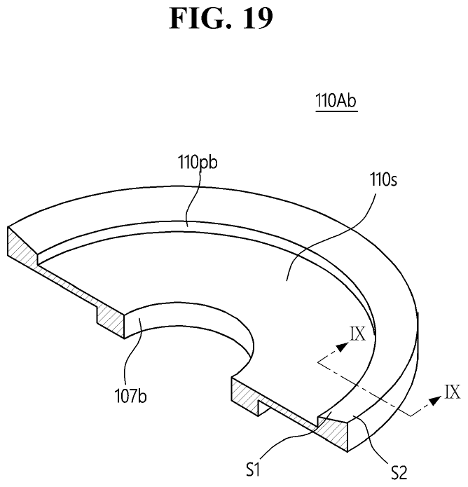

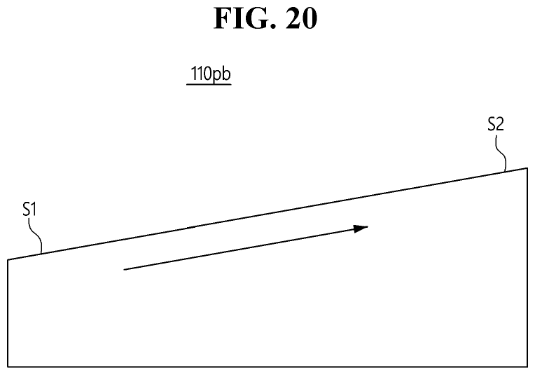

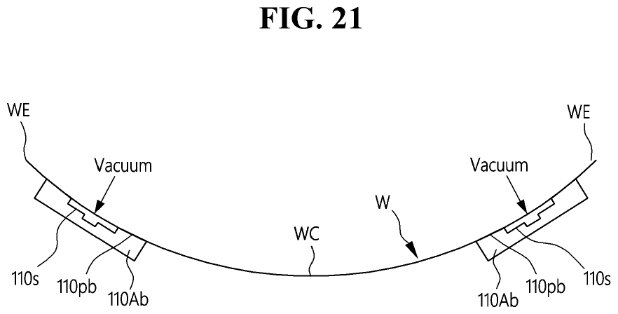

FIG. 18 is an example view for describing a vacuum pad included in the substrate transferring apparatus according to some still other example embodiments. FIG. 19 is a cross-sectional view taken along line VIII-VIII of FIG. 18. FIG. 20 is a cross-sectional view taken along line IX-IX of FIG. 19. FIG. 21 is an example view for describing a substrate vacuum adsorbed by the vacuum pad illustrated in FIG. 18. Hereinafter, a vacuum pad included in the substrate transferring apparatus according to some still other example embodiments will be described with reference to FIGS. 18 to 21. In addition, hereinafter, overlapping descriptions with the previous example embodiments may be omitted, and differences will be mainly described, in the interest of brevity.

Referring to FIGS. 18 to 20, unlike illustrated in FIGS. 6 and 7, an upper surface of a support protrusion 110pb of a vacuum pad 110Ab may be formed to have an inclination. In addition, unlike illustrated in FIGS. 12 to 14, a vertical height from a lower surface of the vacuum pad 110Ab to the first area S1 may be lower than a vertical height from the lower surface of the vacuum pad 110Ab to the second area S2. That is, an inclination in which the vertical height measured from the lower surface of the vacuum pad 110Ab gradually increases from an area of the upper surface of the support protrusion 110pb closer to a center or a central part of the vacuum pad 110Ab to an area farther from the center or the central part of the vacuum pad 110Ab may be formed. In this way, the inclination formed on the upper surface of the support protrusion 110pb of the vacuum pad 110Ab may be formed along the direction in which the substrate W is warped when the substrate W sucked by the vacuum pad 110Ab is concavely warped.

For example, as illustrated in FIG. 21, in the case in which the substrate W is concavely warped and the edge WE of the substrate W has a shape protruding more than the center (or a central part) WC of the substrate, the substrate W may not be stably sucked and fixed on the vacuum pad, when the upper surface of the support protrusion 110p is flat without inclination as illustrated in FIG. 7, or the inclination in which the vertical height measured from the lower surface of the vacuum pad 110Aa gradually decreases from the area of the upper surface of the support protrusion 110pa closer to the center or the central part of the vacuum pad 110Aa to the area farther from the center or the central part of the vacuum pad 110Aa is formed as illustrated in FIG. 13. However, in the case in which the upper surface of the support protrusion 110pb of the vacuum pad 110Ab in direct contact with the substrate W is formed to have an inclination along the direction in which the substrate W is concavely warped, the substrate W may be stably sucked and fixed on the support plate 100 (illustrated in FIG. 2) and the vacuum pad 110Ab when the vacuum pad 110Ab vacuum sucks the convexly warped substrate W.

However, the shape of the substrate W vacuum sucked by the vacuum pad 110Ab in which the height of the second area S2 is higher than the height of the first area S1 is not limited to the concave shape in which the edge WE of the substrate protrudes more than the center (or the central part) WC of the substrate. For example, the substrate W vacuum sucked by the vacuum pad 110Ab may have a warped shape corresponding to the inclination formed on the upper surface of the support protrusion 110pb of the vacuum pad 110Ab so as to be stably fixed and sucked by the vacuum pad 110Ab.

Although the illustration of the support plate 100 is omitted for convenience of illustration in FIG. 21, the vacuum pad 110Ab may be detachably coupled to the support plate 100 through the bolt 120A (illustrated in FIG. 2).

In addition, as described above, when the vacuum pad 110Ab is coupled to the support plate 100 by the bolt 120A, the center or the central part of the vacuum pad 110Ab is fixed by the bolt 120A, but the edge portion of the vacuum pad 110Ab is not completely fixed to the support plate 100 and may move up and down by a predetermined interval while having fluidity. Accordingly, when the substrate W has the concavely warped shape, the edge portion of the vacuum pad 110Ab moves up and down by a predetermined interval while having fluidity along the direction in which the substrate W is warped, so that the concavely warped substrate W may be stably sucked and fixed.

In this way, when the vacuum pad 110Aa (illustrated in FIG. 12) and the vacuum pad 110Ab are detachably coupled to the support plate 100 using the bolt 120A, the vacuum pads 110Aa and 110Ab may be freely replaced according to the shape of the substrate W to be transferred by the substrate transferring apparatus 1000 (illustrated in FIG. 1). For example, when the substrate W has a convexly or concavely warped shape, a vacuum pad including a support protrusion having an inclined surface suitable for the direction in which the substrate W is warped may be used by being coupled to the support plate 100. Accordingly, replacement cost may be reduced by transferring the substrate W by replacing only the vacuum pad without having to replace the entire support plate 100 according to the shape of the substrate W.

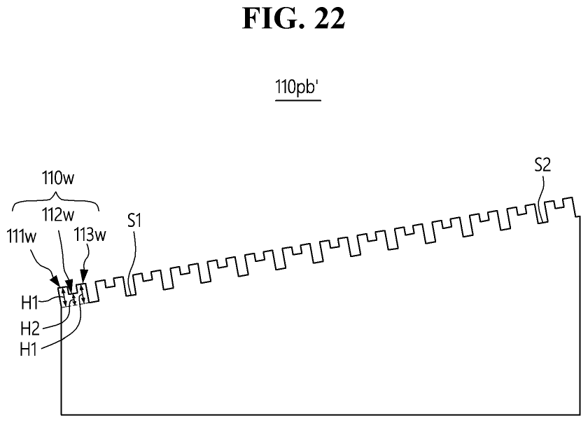

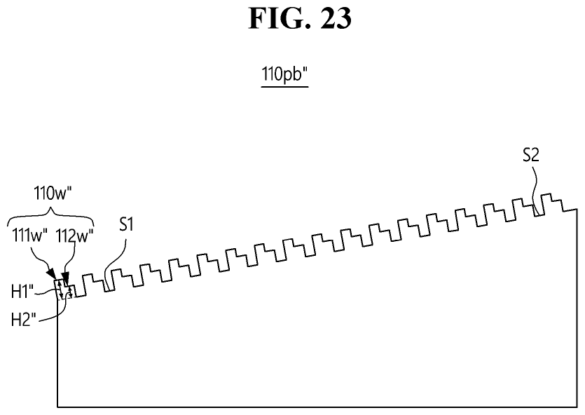

FIGS. 22 and 23 are example views for describing protruding walls formed on upper surfaces of support protrusions of the vacuum pad illustrated in FIG. 18.

Referring to FIGS. 22 and 23, even when an inclination in which the vertical height measured from the lower surface of the vacuum pad 110Ab gradually increases from an area S1 closer to a center or a central part of the vacuum pad 110Ab to an area S2 farther from the center or the central part of the vacuum pad 110Ab is formed on upper surfaces of support protrusions 110pb′ and 110pb″ of the vacuum pad 110Ab, the protrusion walls 110w and 110w″ as shown in FIGS. 9 and 11 may be disposed on the upper surfaces of the support protrusions 110pb′ and 110pb″. Accordingly, the user of the substrate transferring apparatus 1000 (illustrated in FIG. 1) may replace the vacuum pad 110Ab at an appropriate time according to the degree of wear of the protrusion walls 110w and 110w″. Therefore, when the substrate transferring apparatus 1000 transfers the substrate W, it is possible to prevent the substrate W from slipping and being separated from the substrate transferring apparatus 1000 without being stably fixed and sucked on the vacuum pad 110Ab.

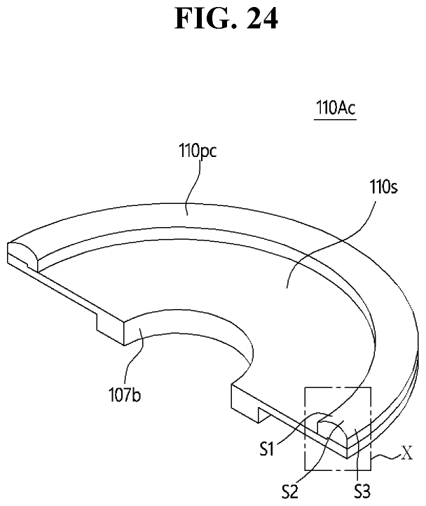

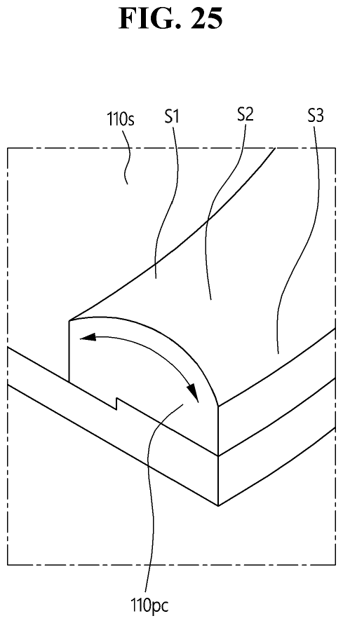

FIG. 24 is an example view for describing a vacuum pad included in the substrate transferring apparatus according to some still other example embodiments. FIG. 25 is an enlarged view of region X of FIG. 24. Hereinafter, a vacuum pad included in the substrate transferring apparatus according to some still other example embodiments will be described with reference to FIGS. 24 and 25. In addition, hereinafter, overlapping descriptions with the previous example embodiments may be omitted, and differences will be mainly described, in the interest of brevity.

FIG. 24 is a cross-sectional view of a vacuum pad 110Ac detachably coupled to the support plate 100 (illustrated in FIG. 2). An upper surface of a support protrusion 110pc of the vacuum pad 110Ac may include a first area or first circumference S1, a second area or second circumference S2, and a third area or third circumference S3. The first area S1 may be closer to a center or a central part of the vacuum pad 110Ac than the second area S2, and the second area S2 may be closer to the center or the central part of the vacuum pad 110Ac than the third area S3. That is, a distance from the first area S1 of the support protrusion 110pc to the center or the central part of the vacuum pad 110Ac may be shorter than a distance from the second area S2 of the support protrusion 110pc to the center or the central part of the vacuum pad 110Ac, and the distance from the second area S2 of the support protrusion 110pc to the center or the central part of the vacuum pad 110Ac may be shorter than a distance from the third area S3 of the support protrusion 110pc to the center or the central part of the vacuum pad 110Ac.

In this case, the upper surface of the support protrusion 110pc may be convexly formed (e.g., rounded) as the second area S2 disposed between the first area S1 and the third area S3 protrudes more or is at a higher vertical level than the first and third areas S1 and S3. In this way, by convexly forming the upper surface of the support protrusion 110pc, the vacuum pad 110Ac may vacuum suck and support the substrate W according to a direction in which the substrate W is concavely or convexly warped, when the substrate W seated on the support plate 100 has a concavely or convexly warped shape. By using the vacuum pad 110Ac that may be used universally in both cases where the substrate W is concavely or convexly warped, coupled to the support plate 100 without having to replace the vacuum pad coupled to the support plate 100 along the direction in which the substrate W is warped, the replacement cost of the vacuum pad may be reduced and the backup time may be shortened.

In addition, according to some example embodiments, the support protrusion 110pc of the vacuum pad 110Ac may include a ceramic material such as aluminum oxide (Al₂O₃) or sintered silicon carbide (SSiC), and the suction area 110s may include a plastic material such as Ertalyte. Accordingly, when the substrate W seated on the support plate 100 is in a high-temperature state, the maintenance cost of the vacuum pad 110Ac may be reduced by implementing only the support protrusion 110pc in direct contact with the substrate W with a ceramic material with strong heat resistance, and implementing the suction area 110s, which is not in direct contact with the high-temperature substrate W, with a relatively inexpensive plastic material.

Although the embodiments of the present disclosure have been described with reference to the accompanying drawings, the present disclosure is not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A substrate transferring apparatus comprising:
a support plate including an upper surface on which a substrate is configured to be seated; and
a vacuum pad detachably coupled to the support plate and configured to vacuum suction the substrate to fix the substrate on the upper surface of the support plate,
wherein the vacuum pad includes:
a suction area; and
a support protrusion surrounding the suction area,
an upper surface of the support protrusion is at a higher vertical level than an upper surface of the suction area to support the substrate, and
the upper surface of the support protrusion is inclined relative to horizontal.

2. The substrate transferring apparatus of claim 1, wherein the support plate includes:
a first supporting arm extending in a first direction;
a second supporting arm spaced apart from the first supporting arm in a second direction intersecting the first direction and extending in the first direction; and
a connecting arm connecting the first supporting arm and the second supporting arm and extending in the second direction.

3. The substrate transferring apparatus of claim 1, wherein the vacuum pad is coupled to the support plate through a bolt.

4. The substrate transferring apparatus of claim 1, wherein when the substrate is seated on the upper surface of the support plate, the substrate is spaced apart from the upper surface of the suction area.

5. The substrate transferring apparatus of claim 1, wherein the upper surface of the support protrusion includes a first area and a second area, and
a distance from the first area to a central part of the vacuum pad is shorter than a distance from the second area to the central part of the vacuum pad.

6. The substrate transferring apparatus of claim 5, wherein a height of the upper surface of the support protrusion decreases from the first area to the second area.

7. The substrate transferring apparatus of claim 5, wherein a height of the upper surface of the support protrusion increases from the first area to the second area.

8. The substrate transferring apparatus of claim 5, wherein the upper surface of the support protrusion further includes a third area,
the distance from the second area to the central part of the vacuum pad is shorter than a distance from the third area to the central part of the vacuum pad, and
the upper surface of the support protrusion is convex with the second area at a higher vertical level than the first and third areas.

9. A substrate transferring apparatus comprising:
a support plate including an upper surface on which a substrate is configured to be seated, a coupling groove extending downward from the upper surface, a first bolt insertion hole defined in a central part of the coupling groove, and a bolt fastener in the first bolt insertion hole;
a vacuum pad in the coupling groove, the vacuum pad including a suction area, a support protrusion surrounding the suction area, and a second bolt insertion hole defined in a central part of the suction area; and
a bolt simultaneously penetrating through the first bolt insertion hole and the second bolt insertion hole and fastened to the bolt fastener,
wherein the bolt includes a vacuum hole penetrating therethrough, and
the vacuum hole is connected to a vacuum passage defined inside the support plate.

10. The substrate transferring apparatus of claim 9, wherein an upper surface of the support protrusion is at higher vertical level than an upper surface of the suction area to support the substrate, and
when the substrate is seated on the upper surface of the support plate, the substrate is spaced apart from the upper surface of the suction area.

11. The substrate transferring apparatus of claim 10, wherein the support protrusion includes a ceramic material, and
the suction area includes a plastic material.

12. The substrate transferring apparatus of claim 11, wherein the support protrusion includes aluminum oxide (Al₂O₃) or sintered silicon carbide (SSiC).

13. The substrate transferring apparatus of claim 9, further comprising a protrusion wall on an upper surface of the support protrusion,
wherein the protrusion wall includes a first protrusion having a first height and a second protrusion having a second height, and
the first height is higher than the second height.

14. The substrate transferring apparatus of claim 13, wherein the first and second protrusions extend in a concentric circle shape surrounding the suction area on the upper surface of the support protrusion.

15. The substrate transferring apparatus of claim 14, wherein the protrusion wall includes a plurality of protrusion walls, and the plurality of protrusion walls extend in a concentric circle shape surrounding the suction area on the upper surface of the support protrusion.

16. The substrate transferring apparatus of claim 13, wherein a ratio of the second height to the first height is ⅖ or more and ⅘ or less.

17. The substrate transferring apparatus of claim 13, wherein the protrusion wall further includes a third protrusion having the first height, and the second protrusion is between the first protrusion and the third protrusion.

18. A substrate transferring apparatus comprising:
a first supporting arm extending in a first direction and including an upper surface on which a substrate is configured to be seated;
a second supporting arm spaced apart from the first supporting arm in a second direction intersecting the first direction, extending in the first direction, and having an upper surface on which the substrate is configured to be seated;
a connecting arm connecting the first supporting arm and the second supporting arm and extending in the second direction; and
a vacuum pad on the upper surface of at least one of the first supporting arm and the second supporting arm and configured to vacuum suction the substrate to fix the substrate on the upper surface of at least one of the first supporting arm and the second supporting arm,
wherein the vacuum pad includes a base and a support protrusion surrounding the base, and is detachably coupled to at least one of the first and second supporting arms by a bolt,
the bolt is coupled to a central part of the vacuum pad,
an upper surface of the support protrusion is at a higher vertical level than an upper surface of the base to support the substrate,
the upper surface of the support protrusion is inclined relative to horizontal,
a protrusion wall is on the upper surface of the support protrusion,
the protrusion wall includes a first protrusion having a first height and a second protrusion having a second height, and
the first height is higher than the second height.

19. The substrate transferring apparatus of claim 18, wherein the bolt includes a vacuum hole penetrating through an inside thereof and configured to provide vacuum pressure.

20. The substrate transferring apparatus of claim 19, wherein a suction hole connected to the vacuum hole is on an upper surface of the bolt.
